(19) United States
(12) Patent Application Publication
(10) Pub. No.: US 2024/0090250 A1
(43) Pub. Date: Mar. 14, 2024

(54) LIGHT EMITTING ELEMENT, DISPLAY DEVICE, AND METHOD FOR PRODUCING LIGHT-EMITTING ELEMENT

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/767,652

(22) PCT Filed: Aug. 26, 2020
(86) PCT No.: PCT/JP2020/032115

§ 371 Date: Apr. 8, 2022

(30) Foreign Application Priority Data
Oct. 16, 2019 (JP) 2019-189065

(51) Int. Cl. H10K 50/115

(52) U.S. Cl. CPC H10K 50/115

(57) ABSTRACT

Provided is a technique for improving a luminous efficiency of a light-emitting element including quantum dots in a light-emitting layer by improving a balance between electrons and positive holes in the quantum dot layer. A light-emitting element according to the disclosure includes an anode, a cathode, and a quantum dot layer provided between the anode and the cathode and including a plurality of quantum dots and a vacancy, the vacancy being a region between the plurality of quantum dots. The quantum dot layer includes both the plurality of quantum dots and the vacancy in the quantum dot layer in an entire region of the quantum dot layer in each of all cross sections having a normal line in a direction from the cathode toward the anode.

### TECHNICAL FIELD

The disclosure relates to a light-emitting element, a display device, and a method for manufacturing a light-emitting element. This application claims priority based on Japanese Patent Application No. 2019-189065 filed in Japan on Oct. 16, 2019, the contents of which are incorporated herein by reference.

### BACKGROUND ART

A light-emitting element described in PTL 1 includes a light-emitting layer containing quantum dots. In the light-emitting element described in PTL 1, a density of the quantum dots in a thickness direction of the light-emitting layer decreases from an anode side toward a cathode side.

### CITATION LIST

### Patent Literature

PTL 1: JP 2009-87755 A

### SUMMARY OF INVENTION

### Technical Problem

In the light-emitting element of PTL 1, a coverage rate of quantum dots on the cathode side (electron transport layer side) of the light-emitting layer is about 10%, and thus the quantum dots are considered not necessary. Accordingly, in PTL 1, the cathode side of the light-emitting layer has a large percentage of vacancy, the vacancy being a region in which the quantum dots are not present, compared to the anode side. However, as in the light-emitting element described in PTL 1, because the coverage rate of quantum dots on the cathode side of the light-emitting layer is about 10%, when the percentage of the vacancy is increased to the extent that the quantum dots are no longer present, the barrier to electrons becomes extremely large in the light-emitting layer, causing the number of electrons in the light-emitting layer to be insufficient with respect to the positive holes. As a result, the recombination rate between electrons and positive holes in the light-emitting layer decreases, and luminous efficiency (external quantum efficiency) of the light-emitting element decreases.

An object of a light-emitting element according to one aspect of the disclosure is to improve luminous efficiency.

### Solution to Problem

A light-emitting element according to one aspect of the disclosure includes an anode, a cathode, and a quantum dot layer provided between the anode and the cathode and including a plurality of quantum dots and a vacancy, the vacancy being a region between the plurality of quantum dots. The quantum dot layer includes both the plurality of quantum dots and the vacancy in the quantum dot layer in an entire region of the quantum dot layer in all cross sections having a normal line in a direction from the cathode toward the anode.

### Advantageous Effects of Invention

According to one aspect of the disclosure, it is possible to realize a light-emitting element having improved luminous efficiency.

### BRIEF DESCRIPTION OF DRAWINGS

FIG. 1 is a cross-sectional view schematically illustrating a display device according to a first embodiment.

FIG. 2 is a cross-sectional view schematically illustrating a light-emitting element according to the first embodiment.

FIG. 3 is a schematic view illustrating an energy distribution in a quantum dot layer according to the first embodiment.

FIG. 4 is a flowchart illustrating an example of a method for manufacturing the light-emitting element according to the first embodiment.

FIG. 5 is a table showing characteristic values of light-emitting elements according to examples 1-1 to 1-5 and comparative examples 1 and 2.

FIG. 6 is a flowchart illustrating an example of a method for manufacturing the light-emitting element according to a second embodiment.

FIG. 7 is an enlarged cross-sectional view schematically illustrating an example of a portion of the light-emitting element according to the second embodiment.

FIG. 8 is an enlarged cross-sectional view schematically illustrating another example of a portion of the light-emitting element according to the second embodiment.

FIG. 9 is an enlarged cross-sectional view schematically illustrating another example of a portion of the light-emitting element according to the second embodiment.

FIG. 10 is a cross-sectional view schematically illustrating the light-emitting element according to an embodiment of the present invention.

### DESCRIPTION OF EMBODIMENTS

Hereinafter, exemplary embodiments and examples of the disclosure will be described with reference to the drawings. Note that description of duplicate items in each of the embodiments and the examples will be omitted as appropriate. Further, in the following, a “same layer” means that the layer is formed through the same process (film formation process), a “lower layer” means that the layer is formed in a process before the layer being compared, and an “upper layer” means that the layer is formed in a process after the layer being compared.

### First Embodiment

FIG. 1 is a cross-sectional view schematically illustrating a display device 10 according to a first embodiment. The display device 10 of the present embodiment is a display device that uses a quantum-dot light emitting diode (QLED) as a light source, and includes light-emitting elements 20, which include quantum dots, above a first film 11 having flexibility and a resin layer 12, for example.

The display device 10 has a structure in which the resin layer 12, a barrier layer 13, a thin film transistor (hereinafter. TFT) layer 14 including TFTs, a light-emitting element layer 15 including the light-emitting elements 20 and cover films 151, a sealing layer 16, and a second film 17 are layered in this order on an upper layer of the first film 11.

The first film 11 is a support member in the display device 10 having flexibility. The first film 11 can be formed of a material having flexibility such as polyethylene terephthalate (PET), for example. Note that, in a case in which the display device 10 does not require flexibility, a substrate formed of a hard material such as glass may be used as the support member instead of the first film 11.

The resin layer 12 is provided between the first film 11 and the barrier layer 13. The resin layer 12 is a layer used for peeling a support substrate (not illustrated) used in a manufacturing process of the display device 10 from the barrier layer 13 and bonding the first film 11 having flexibility to the barrier layer 13. The resin layer 12 is partially removed when the support substrate is peeled from the barrier layer 13. The resin layer 12 may have a multilayer structure in which a plurality of resin films are layered, or may have a multilayer structure in which an inorganic film is interposed between a plurality of resin films. Note that, in a case in which the display device 10 does not require flexibility, the resin layer 12 may be omitted.

The barrier layer 13 is a layer for preventing foreign matters such as water and oxygen from entering the TFT layer 14 and the light-emitting element layer 15. The barrier layer 13 is a single layer or a multilayer insulating film, and can be formed of an insulating material, such as silicon oxide, silicon nitride, or silicon oxynitride, for example.

The TFT layer 14 includes a semiconductor film 141, a gate insulating film 142 in an upper layer above the semiconductor film 141, and a gate electrode GE and a gate wiring line (not illustrated) in an upper layer above the gate insulating film 142. Further, the TFT layer 14 includes a first insulating film 143 in an upper layer above the gate electrode GE and the gate wiring line, a capacitance electrode CE in an upper layer above the first insulating film 143, and a second insulating film 144 in an upper layer above the capacitance electrode CE. The TFT layer 14 includes a source wiring line SW and a drain wiring line DW (not illustrated) in an upper layer above the second insulating film 144, and a flattening film 145 in an upper layer above the source wiring line SW and the drain wiring line DW.

The TFT includes the semiconductor film 141, the gate insulating film 142, the gate electrode GE, the first insulating film 143, and the second insulating film 144. A source region and a drain region (not illustrated) of the semiconductor film 141 are regions in which high concentration doping is performed on an upper face of the semiconductor film 141, and function as a source electrode and a drain electrode. The source wiring line SW and the drain wiring line DW are respectively connected to the source region and the drain region via contact holes passing through the gate insulating film 142, the first insulating film 143, and the second insulating film 144. The gate electrode GE is connected to a gate wiring line (not illustrated), and the gate wiring line is connected to a driver integrated circuit (IC; not illustrated). The source wiring line SW is connected to a driver IC (not illustrated). The drain wiring line DW is connected to a pixel electrode (not illustrated).

The semiconductor film 141 can be formed of, for example, a semiconductor material such as low-temperature polysilicon (LTPS) or an oxide semiconductor (for example, an In—Ga—Zn—O based semiconductor). The gate electrode GE, the gate wiring line, the capacitance electrode CE, the drain wiring line DW, and the source wiring line SW are single layer or multilayer conductive films.

The first insulating film 143 and the second insulating film 144 are single layer or multilayer insulating films, and can be formed of an insulating material, such as silicon oxide or silicon nitride, for example.

The flattening film 145 is a film layered on the TFT for flattening irregularities formed by the TFT. The flattening film 145 can facilitate layering the light-emitting element layer 15 thereon.

Note that although a structure of the TFT included in the TFT layer 14 is illustrated as a top gate type in FIG. 1, the structure of the TFT may be a bottom gate type or a double gate type. The TFT is a switching element that controls light emission of the light-emitting element 20. One TFT is connected to one light-emitting element 20. In FIG. 1, the drain region of the TFT and an anode 21 of the light-emitting element 20 are connected to each other via the contact hole formed in the flattening film 145 and the drain wiring line DW provided in the TFT layer 14.

The light-emitting element layer 15 includes a plurality of the light-emitting elements 20 and the cover films 151. The plurality of light-emitting elements 20 are provided in a matrix shape in a display region of an image in the display device 10. FIG. 1 illustrates a structure in which the plurality of light-emitting elements 20 share one cathode 26. The shape of the cathode 26 is not limited to the structure of FIG. 1. For example, the structure may be such that each light-emitting element 20 includes a separate cathode 26. Further, FIG. 1 illustrates a structure in which each light-emitting element 20 includes a separate anode 21. The shape of the anode 21 is not limited to the structure in FIG. 1. For example, the structure may be such that the plurality of light-emitting elements 20 share one anode 21.

The cover films 151 are provided between the plurality of light-emitting elements 20, covering a side surface of each light-emitting element 20 and an end portion of each anode 21. The cover film 151 is provided in a lattice pattern in the display region. The cover film 151 is an insulating film, and can be formed of an organic material, for example.

The sealing layer 16 is a layer for preventing foreign matters such as water and oxygen from entering the TFT layer 14 and the light-emitting element layer 15 by sealing the light-emitting element layer 15. FIG. 1 illustrates a case in which the sealing layer 16 has a triple-layer structure. The sealing layer 16 includes a first sealing film 161 covering the cathode 26, a second sealing film 162 covering the first sealing film 161, and a third sealing film 163 covering the second sealing film 162. The sealing layer 16 is not limited to the triple-layer structure. For example, the sealing layer 16 may have a structure of any number of layers including a single layer.

For example, the first sealing film 161 and the third sealing film 163 are single layer or multilayer inorganic insulating films, and can be formed of an inorganic material such as a silicon oxide film, a silicon nitride film, and a silicon oxynitride film. The second sealing film 162 is, for example, a light-transmissive organic film, and can be formed of a light-transmissive organic material such as acrylic.

The second film 17 can be formed of, for example, a PET film. As a result, the display device 10 having flexibility can be realized. Note that in a case in which the display device 10 does not require flexibility, a hard substrate of glass or the like may be used instead of the second film 17.

Of the first film 11 and the second film 17, the film provided on a light-outputting side of the light-emitting element 20 is the display region side of the display device 10. As the film on the display region side, a function film having an optical compensation function, a touch sensor function, a protection function, or the like can be used, for example.

The light-emitting element 20 of the present embodiment illustrates a configuration in which light is output from the anode 21 side to the outside of the display device 10. Thus, the first film 11, the resin layer 12, the barrier layer 13, and the TFT layer 14 on the light-outputting side are preferably formed of highly light-transmissive material. Further, in the configuration of the display device 10, of the anode 21 and the cathode 26, at least one of the sealing layer 16 and the second film 17 provided on the cathode 26 side, which is the opposite side, preferably has a reflecting function.

Note that the light-emitting element 20 may be configured to output light from the cathode 26 side to the outside of the display device 10. In this case, in the configuration of the display device 10, the sealing layer 16 and the second film 17 provided in a direction in which light is output are preferably formed of highly light-transmissive material. Further, in the configuration of the display device 10, of the anode 21 and the cathode 26, at least one of the first film 11, the resin layer 12, the barrier layer 13, and the TFT layer 14 provided on the anode 21 side, which is the opposite side, preferably has a reflecting function.

Further, although not illustrated, an electronic circuit board and a power circuit board (for example, an IC chip, a driver IC, or a flexible printed circuit (FPC)) are disposed outside the display region of the display device 10. A plurality of the TFTs and the light-emitting elements 20 described above are arrayed on a plane to constitute the display region of the display device 10. Power is supplied from each of the circuits described above to the plurality of TFTs and light-emitting elements 20 arranged on the plane, and each operation is controlled by each of the circuits. Thus, a screen display of the display device 10 is performed.

As the process for preparing the display device 10 of the present embodiment, first, the resin layer 12 is formed in an upper layer above the support substrate (resin layer 12 forming process). Next, the barrier layer 13 is formed in an upper layer above the resin layer 12. Next, the TFT layer 14 including the TFTs is formed in an upper layer above the barrier layer 13. Next, the light-emitting element layer 15 including the bottom-emitting type light-emitting elements 20 is formed in an upper layer above the TFT layer 14. Next, the sealing layer 16 is formed in an upper layer above the light-emitting element layer 15. Next, the second film 17 is bonded to an upper layer above the sealing layer 16.

Laser light is transmitted through the support substrate and irradiated onto the resin layer 12. As a result, the resin layer 12 is partially removed, and the support substrate is peeled from the resin layer 12 (support substrate peeling process). Next, the first film 11 is bonded to a lower face of the resin layer 12 from which the support substrate was peeled (bonding process). Next, the layered body including the first film 11, the resin layer 12, the barrier layer 13, the TFT layer 14, the light-emitting element layer 15, the sealing layer 16, and the second film 17 is divided to obtain a plurality of individual pieces. Next, the electronic circuit board is disposed on a portion of a non-display region outside the display region. Note that these processes are performed by a manufacturing apparatus of the display device 10.

In a case of manufacture of the display device 10 that does not require flexibility, the resin layer 12 forming process, the support substrate peeling process, and the first film 11 bonding process are not necessary. In this case, for example, the first film 11 need only be replaced with a glass substrate or the like, and the barrier layer 13 forming process and subsequent processes need only be performed. Further, a method corresponding to the material of each layer, such as an application method, sputtering, a photolithography method, or chemical vapor deposition (CVD) can be used as appropriate as a method for layering each layer in the processes described above.

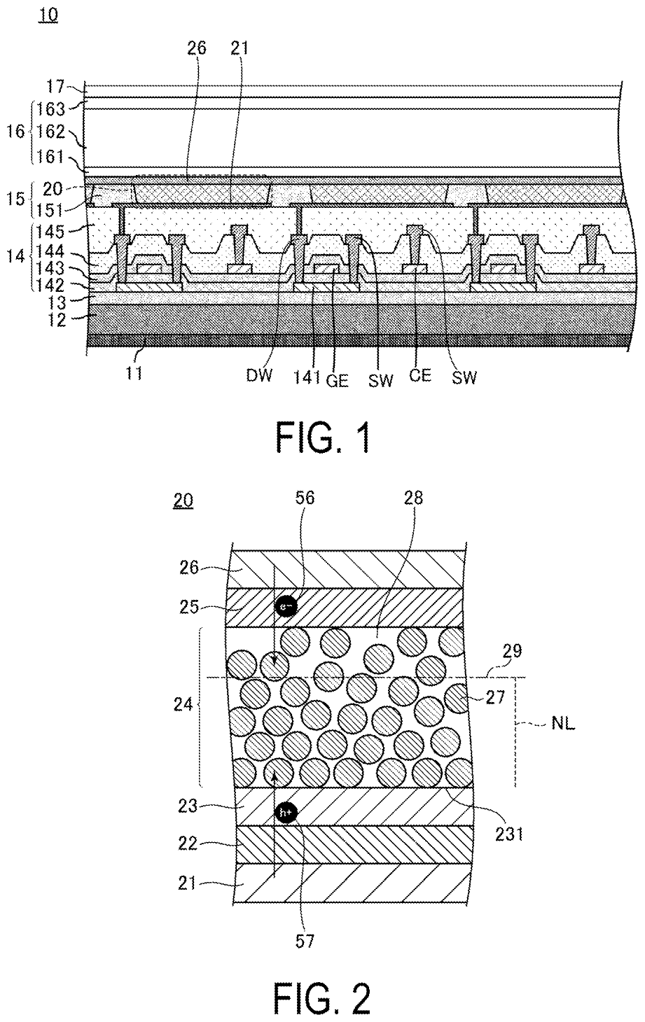

FIG. 2 is a cross-sectional view schematically illustrating the light-emitting element 20 according to the first embodiment. The light-emitting element 20 of the present embodiment includes the anode 21, a hole injection layer 22, a hole transport layer 23, a quantum dot layer 24, an electron transport layer 25, and the cathode 26, and is configured by layering these in this order. Note that, in the present embodiment, a direction from the cathode 26 toward the anode 21 is referred to as a downward direction, and a direction from the anode 21 toward the cathode 26 is referred to as an upward direction. Details of the light-emitting element 20 will be described below.

The anode 21 is an electrode for injecting positive holes into the quantum dot layer 24. The cathode 26 is an electrode for injecting electrons into the quantum dot layer 24. The anode 21 and the cathode 26 can be formed of a conductive material. The anode 21 is in contact with the hole injection layer 22. The cathode 26 is in contact with the electron transport layer 25.

For example, one of the anode 21 and the cathode 26 is a light-transmissive electrode and the other is a non-light-transmissive electrode. The light-transmissive electrode can be formed of a conductive material such as ITO, IZO, ZnO, AZO, BZO, or FTO, for example. The non-light-transmissive electrode can be formed of a metal material having high light reflectivity such as Al, Cu, Au, Ag, Mg, or alloys thereof, for example. With use of a material having high light reflectivity as the non-light-transmissive electrode, the light emitted by the quantum dot layer 24 can be reflected in the direction in which light is output from the light-emitting element 20. In the present embodiment, the light emitted by the quantum dot layer 24 is reflected by the cathode 26, transmitted through the anode 21, and output from the light-emitting element 20 to the outside of the display device 10.

The hole injection layer 22 is a layer for injecting positive holes from the anode 21 into the hole transport layer 23. The hole transport layer 23 is a layer for transporting positive holes injected from the hole injection layer 22 to the quantum dot layer 24. Note that, of the hole injection layer 22 and the hole transport layer 23, only the hole injection layer 22 may be provided between the anode 21 and the quantum dot layer 24, or the hole injection layer 22 and the hole transport layer 23 may be omitted and the anode 21 and the quantum dot layer 24 may be directly in contact with each other.

The hole injection layer 22 and the hole transport layer 23 can be formed of an organic material containing a conductive compound such as PEDOT-PSS, TFB, and PVK, or an inorganic material containing a metal oxide such as NiO, Cr₂O₃, MgO, MgZnO, LaNiO₃, MoO₃, and WO₃, for example.

The electron transport layer 25 is provided between the quantum dot layer 24 and the cathode 26. One surface of the electron transport layer 25 is in contact with the quantum dot layer 24, and the other surface is in contact with the cathode 26. The electron transport layer 25 is a layer for transporting electrons from the cathode 26 to the quantum dot layer 24.

The electron transport layer 25 can be formed of a metal oxide film such as TiO₂, ZnO, ZAO, ZnMgO, ITO, or an In—Ga—Zn—O based semiconductor, for example. Further, the electron transport layer 25 can be formed of a conductive polymer material such as Alq3, BCP, or t-Bu-PBD.

The material of the electron transport layer 25 is desirably a material having a small electron affinity or work function to facilitate the injection of electrons from the cathode 26. Further, the material of the electron transport layer 25 is desirably a stable material having high physical durability to prevent foreign matters such as water and oxygen from entering the quantum dot layer 24. Accordingly, an inorganic material is suitable for the material of the electron transport layer 25. Inorganic materials typically have high electron mobility, and have high carrier density of electrons. Thus, the injection density of electrons into the quantum dot layer 24 can be increased by using an inorganic material for the electron transport layer 25.

The quantum dot layer 24 emits light as a result of an occurrence of recombination between positive holes 57 injected from the anode 21 and electrons 56 injected from the cathode 26. The quantum dot layer 24 is provided between the anode 21 and the cathode 26. The quantum dot layer 24 includes quantum dots 27 that are nano-sized semiconductor particles and a vacancy 28 that is a region in which the quantum dots 27 are not included. The quantum dot layer 24 is layered so as to include both a plurality of the quantum dots 27 and the vacancy 28 in all cross sections 29 orthogonal to a normal line NL, the normal line NL being a direction from the anode 21 toward the cathode 26. In the present embodiment, the quantum dot layer 24 is provided in contact with a contact surface 231, which is the surface of the hole transport layer 23.

A particle size of the quantum dots 27 is, for example, from about 2 to 15 nm. The smaller the particle size of the quantum dots 27, the shorter the light emission wavelength, changing the luminescent color from red to green and from green to blue. Thus, the light emission wavelength of the light-emitting element 20 can be controlled by changing the particle size of the quantum dots 27. When the display device 10 of the present embodiment is configured, a red light-emitting element 20, a green light-emitting element 20, and a blue light-emitting element 20 are arrayed as one set in the light-emitting element layer 15.

The cross section 29 is a virtual plane when, with respect to a plane on the cathode 26 side and a plane on the anode 21 side of the quantum dot layer 24, the quantum dot layer 24 is cut in a direction parallel to both of these planes (left-right direction in FIG. 2). In the present embodiment, a direction parallel to the cross section 29 may be referred to as a horizontal direction. Further, the cross section 29 can also be expressed as being orthogonal to a thickness direction of the quantum dot layer 24. The normal line NL is a virtual line extending in a direction orthogonal to the cross section 29 (up-down direction in FIG. 2). In the present embodiment, the direction in which the normal line NL extends may be referred to as a vertical direction. Further, the normal line NL can also be expressed as being parallel to the thickness direction of the quantum dot layer 24. That is, in the quantum dot layer 24, the vacancy 28 and the quantum dots 27 are disposed so that both the vacancy 28 and the quantum dots 27 are always included in the cross section 29, even when the cross section 29 orthogonal to the thickness direction is cut at any position (arbitrary position) in the thickness direction of the quantum dot layer 24.

An outer shape of the quantum dots 27 is a spherical shape, and thus the entire region of the quantum dot layer 24 cannot be filled with the quantum dots 27, in principle. Thus, the vacancy 28 always exists in the quantum dot layer 24. Accordingly, “both the vacancy 28 and the quantum dots 27 are always included” in the description above specifically means that, in the cross section 29 of the quantum dot layer 24, at any position in the thickness direction, there is no cross section 29 with only the vacancy 28, and the quantum dots 27 are always included in the cross section 29.

In the present embodiment, the vacancy 28 is the space between the plurality of quantum dots 27, and a gas such as air, nitrogen, or hydrogen, for example, may be present. The vacancy 28 may be space having a level close to a vacuum level with respect to electron transport. Further, in the vacancy 28, an insulating solvent may be present as a liquid or an insulating solid may be present. Furthermore, in the vacancy 28, a solvent and a material that is different from the quantum dots 27 and having much lower conductivity than the quantum dots 27, or the like, may be present.

According to the above-described configuration of the light-emitting element 20, when a potential difference is applied between the anode 21 and the cathode 26, the positive holes 57 are injected from the anode 21 and the electrons 56 are injected from the cathode 26, toward the quantum dot layer 24, as illustrated in FIG. 2. The positive holes 57 reach the quantum dot layer 24 via the hole injection layer 22 and the hole transport layer 23. Further, the electrons 56 reach the quantum dot layer 24 via the electron transport layer 25. The positive holes 57 and the electrons 56 that have reached the quantum dot layer 24 recombine with each other in the interior of the quantum dots 27, and light is output from the quantum dot layer 24. As described above, the light-emitting element 20 emits light.

When the density of electrons becomes exceedingly higher than that of positive holes in the interior of the quantum dot layer, there are many excessive electrons that cannot recombine with positive holes in the quantum dot layer, and the density of the positive holes in the quantum dot layer decreases. As a result, the recombination rate of the quantum dot layer decreases, and the luminous efficiency of the light-emitting element decreases. Further, when the percentage of the interior of the quantum dot layer occupied by the vacancy becomes too large, conversely there are not enough electrons for the positive holes, and the recombination rate in the quantum dot layer decreases.

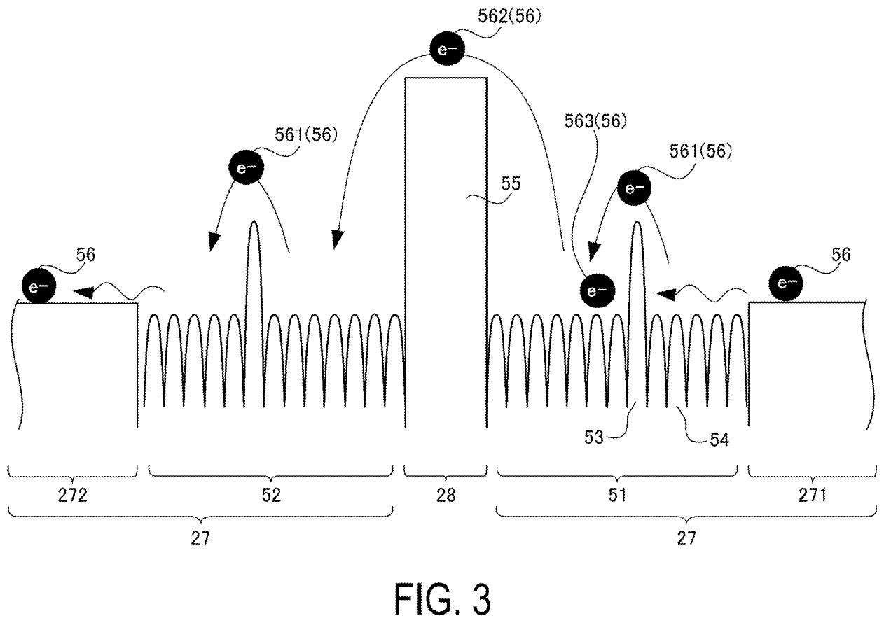

In the light-emitting element 20 of the present embodiment, the quantum dot layer 24 includes both the plurality of quantum dots 27 and the vacancy 28 in the quantum dot layer 24 in all cross sections 29 orthogonal to the normal line NL, the normal line NL being the direction from the cathode 26 toward the anode 21. With this configuration, it is possible to keep the influence of the vacancy 28 from becoming large (described below with reference to FIG. 3). Accordingly, a favorable balance between the electrons 56 and the positive holes 57 in the quantum dot layer 24 can be maintained, and the luminous efficiency of the light-emitting element 20 can be increased.

In a case in which the light-emitting element 20 outputs light from the cathode 26 side to the outside, the electron transport layer 25 and the cathode 26 are each formed of a light-transmissive material, and are preferably formed of a material having a light transmittance of 95% or greater, for example. As a result, attenuation of light emitted from the quantum dot layer 24 to the outside due to the electron transport layer 25 and the cathode 26 can be suppressed.

Next, the flow of electrons in the quantum dot layer 24 will be described using FIG. 2 and FIG. 3. FIG. 3 is a schematic energy diagram illustrating the transmission of electrons between two quantum dots 27 adjacent to each other across the vacancy 28 in the quantum dot layer 24 of FIG. 2. In FIG. 3, the height direction represents energy potential. Here, in the quantum dot layer 24 in FIG. 2, the two quantum dots 27 adjacent to each other across the vacancy 28 are referred to as a first quantum dot and a second quantum dot, respectively, from the side closer to the cathode 26.

In FIG. 3, the first quantum dot corresponds to a first quantum dot main body 271, which includes a core, and a first ligand 51 coupled to an outer face of the first quantum dot main body 271. The second quantum dot corresponds to a second quantum dot main body 272, which includes a core, and a second ligand 52 coupled to an outer face of the second quantum dot main body 272. The vacancy 28 is present between the first ligand 51 and the second ligand 52. The first ligand 51 and the second ligand 52 are organic compounds having electrical conductivity.

In FIG. 3, the energy of the first quantum dot main body 271 is illustrated on the rightmost side, the energy of the first ligand 51 is illustrated on the left of the first quantum dot main body 271, the energy of the barrier 55 due to the vacancy 28 is illustrated on the left side of the first ligand 51, the energy of the second ligand 52 is illustrated on the left of the barrier 55, and the energy of the second quantum dot main body 272 is illustrated on the leftmost side.

As illustrated in FIG. 2, the electrons 56 injected from the cathode 26 of the light-emitting element 20 are injected into the quantum dot layer 24 via the electron transport layer 25. As illustrated in FIG. 3, the electrons 56 move from the first quantum dot main body 271 to the second quantum dot main body 272 via the first ligand 51 and the second ligand 52. By the electrons 56 being transferred between adjacent quantum dots 27, the electrons 56 are moved within the quantum dot layer 24.

The first ligand 51 and the second ligand 52 each include an organic molecular group. The barrier 53 is a barrier formed by, among the organic molecular groups respectively contained in the first ligand 51 and the second ligand 52, organic molecular groups aggregated without chemical bonding. The barrier 54 is a barrier formed by, among the organic molecular groups respectively contained in the first ligand 51 and the second ligand 52, organic molecular groups chemically bonded. The aggregated organic molecular groups do not have a bond that serves as an electron transport path, making it more difficult for the electrons 56 to move than in the organic molecular groups chemically bonded. Thus, the barrier 53 is larger than the barrier 54. Note that, when the aggregated organic molecular groups are in close contact and an electrical field of a certain degree is applied, the electrons 56 can easily cross the barrier 53. Thus, of the electrons 56, electrons 561 that cross the barrier 53 can be easily moved in the first ligand 51 and the second ligand 52.

The vacancy 28 is a region having extremely low electrical conductivity or a region having insulating properties. Thus, the barrier 55 formed by the vacancy 28 is very large between the first ligand 51 and the second ligand 52. Therefore, the barrier 55 is much larger than the barrier 53 and the barrier 54 formed in the first ligand 51 and the second ligand 52 that include the organic molecular groups having electrical conductivity. Therefore, among the electrons 56 that cross the barrier 53 and the barrier 54 formed in the first ligand 51, only a portion of electrons 562 can cross the barrier 55 and move from the first ligand 51 side to the second ligand 52 side. Among the electrons 56 that cross the barrier 53 and the barrier 54 in the first ligand 51, remaining electrons 563 that cannot cross the barrier 55 remain on the first ligand 51 side. Thus, the movement of the electrons 56 between the plurality of quantum dots 27 can be suppressed by the barrier 55 formed by the vacancy 28.

The number of the electrons 56 in the quantum dot layer 24 is large in the position of the electron transport layer 25 side, and small in the position of the hole transport layer 23 side. Further, in the quantum dot layer 24, the electrons 563 are retained at or near an interface with the electron transport layer 25, and thus the electrons 56 are less likely to be transported from the electron transport layer 25 toward the quantum dot layer 24. Accordingly, the density of the electrons 56 in the quantum dot layer 24 can be suppressed by the vacancy 28.

If, as in the light-emitting element described in PTL 1, a portion of the region of the quantum dot layer in the layering direction includes a region in which the percentage of the vacancy is too large, the height of the barrier formed by the vacancy increases excessively and the electrons can no longer cross the barrier formed by the vacancy. As a result, the luminous efficiency in the quantum dot layer is lowered. On the other hand, as described using FIG. 2, in the light-emitting element 20 of the present embodiment, the quantum dot layer 24 includes both the plurality of quantum dots 27 and the vacancy 28 in the quantum dot layer 24 in all cross sections 29 orthogonal to the normal line NL, the normal line NL being the direction from the cathode 26 toward the anode 21. This makes it possible to ensure that the height and the width of the barrier 55 formed by the vacancy 28 illustrated in FIG. 3 are not too great, that is, that the influence of the vacancy 28 is not too large. As a result, the balance between the electrons 56 and the positive holes 57 in the quantum dot layer 24 can be favorably maintained, and thus the luminous efficiency of the light-emitting element 20 can be increased.

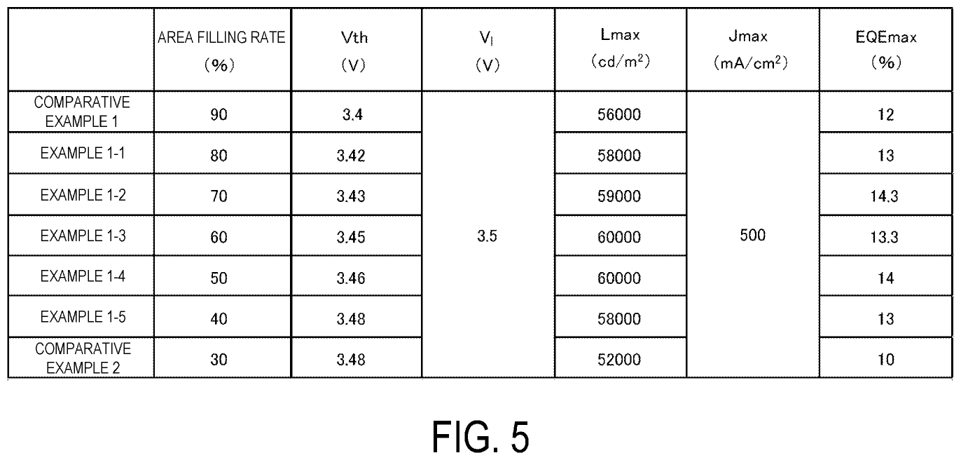

The quantum dot layer 24 preferably has an area filling rate from 40% to 80%, the area filling rate being a percentage of all cross sections 29 orthogonal to the normal line NL occupied by the plurality of quantum dots 27 in the quantum dot layer 24. Specifically, the area filling rate is the percentage of the cross section 29 occupied by the quantum dots 27. Thus, the height and the width of the barrier 55 formed by the vacancy 28 illustrated in FIG. 3 can each be set in a more optimal range. Accordingly, it is possible to realize the light-emitting element 20 having a higher luminous efficiency. Note that the details of the area filling rate being preferably from 40% to 80% are described below with reference to FIG. 5 and examples 1-1 to 1-5.

FIG. 3 illustrates a case in which the first ligand 51 and the second ligand 52 are respectively present on the surfaces of the first quantum dot main body 271 and the second quantum dot main body 272, but the configuration of the present embodiment applies even in a case in which the quantum dots 27 do not include a ligand. That is, in FIG. 3, even in a case in which the first ligand 51 and the second ligand 52 are not present, the barrier 55 occurs as long as the vacancy 28 exists between the first quantum dot main body 271 and the second quantum dot main body 272. Thus, movement of the electrons 56 is suppressed between the first quantum dot main body 271 and the second quantum dot main body 272.

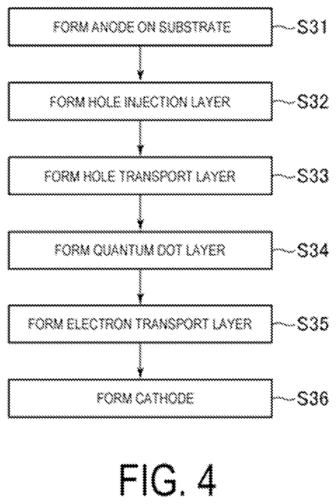

FIG. 4 is a flowchart illustrating a method for manufacturing the light-emitting element 20 according to the first embodiment. In the method for manufacturing the light-emitting element 20, a process of forming the anode 21 (step S31), a process of forming the hole injection layer 22 on the anode 21 (step S32), a process of forming the hole transport layer 23 on the hole injection layer 22 (step S33), a process of forming the quantum dot layer 24 on the hole transport layer 23 (step S34), a process of forming the electron transport layer 25 on the quantum dot layer 24 (step S35), and a process of forming the cathode 26 on the electron transport layer 25 (step S36) are performed in this order. In step S34, the quantum dot layer 24 is formed so that both the plurality of quantum dots 27 and the vacancy 28 in the quantum dot layer 24 are included in the cross section 29 of the quantum dot layer 24.

The method for manufacturing the light-emitting element 20 of the present embodiment will be more specifically described below. First, the anode 21 is formed on the TFT layer 14 with the support substrate on which the TFT layer 14 is formed as a base (step S31). The anode 21 can be formed by layering conductive material on the TFT layer 14 by sputtering, vapor deposition, or metal CVD, for example.

Next, the hole injection layer 22 is formed on the anode 21 (step S32). The hole injection layer 22 can be formed by layering an inorganic material by sputtering, vapor deposition, or metal CVD, for example. Further, the hole injection layer 22 can be formed by layering an organic material by a method of applying a liquid organic material or the like.

Next, the hole transport layer 23 is formed on the hole injection layer 22 (step S33). The hole transport layer 23 can be formed using similar materials by a method similar to that of the hole injection layer 22 described above. Note that either one of step S32 and step S33 may be omitted.

Next, the quantum dot layer 24 is formed on the hole transport layer 23 (step S34). The quantum dot layer 24 can be formed by applying a dispersion in which the quantum dots 27 are dispersed in an organic solvent onto the hole transport layer 23 by a spin coating method or an ink-jet method, for example.

In step S34, examples of parameters affecting the array of the plurality of quantum dots 27 include the particle size of the quantum dots 27, the length of the ligand attached to the surface of the quantum dots 27, the density of the quantum dots 27 in the solvent, temperature, electrostatic force, and solvent viscosity. The array of quantum dots 27 in the quantum dot layer 24 can be adjusted by adjusting these parameters as appropriate. Thus, the quantum dots 27 can be layered so that both the plurality of quantum dots 27 and the vacancy 28 in the quantum dot layer 24 are included across the entire region of the quantum dot layer 24, in all cross sections 29 of the quantum dot layer 24.

For example, the quantum dot layer 24 is formed by a spin coater method. In this case, a colloidal solution in which the quantum dots 27 are dispersed in a solvent, or a resist in which the quantum dots 27 are dispersed is dripped onto a rotating formation surface, spreading and forming the quantum dot layer 24 over the entire formation surface. At this time, the lower the viscosity of the solution and the higher the rotational speed, the greater the number of random minute vortices generated when the solution spreads and the more the solution spreads non-uniformly. With the solution spreading non-uniformly, the vacancy 28 can be formed between the plurality of quantum dots 27 in the quantum dot layer 24. Then, the viscosity and the rotational speed of the solvent can be adjusted as appropriate, and the distribution of the vacancy 28 in the quantum dot layer 24 can be adjusted. For example, as the solvent, a material having a viscosity of less than 0.5 mPa·s, such as toluene, hexane, or pentane, is preferably used. Further, the rotational speed when the solution is applied is preferably less than 3000 rpm, for example.

Further, in the spin coater method, the distribution of the vacancy 28 in the quantum dot layer 24 can be adjusted by dividing the application and formation of the quantum dot layer 24 into two applications, and using solvents having different liquid repellencies in the first application and the second application. For example, in the first application, dodecanethiol having a relatively high liquid repellency is used as a solvent for dispersing the quantum dots 27. Then, the distribution of the quantum dots 27 is non-uniform due to the liquid repellency of the solvent. As a result, the quantum dots 27 are coarsely and densely distributed in the surface of the layer formed by the first application. In the second application, hexadecylamine, oleylamine, or the like having a relatively low liquid repellency is used as the solvent. The coarse and dense distribution on the surface of the layer formed by the first application affects the distribution of the quantum dots 27 applied the second time, forming the vacancy 28.

Next, the electron transport layer 25 is formed on the quantum dot layer 24 (step S35). The electron transport layer 25 can be formed by, for example, sputtering, vapor deposition, and an application method.

Next, the cathode 26 is formed on the electron transport layer 25 (step S36). Similar to the anode 21 described above, the cathode 26 can be formed by layering a conductive material by, for example, sputtering, vapor deposition, or metal CVD.

### Examples 1-1 to 1-5

The following describes specific examples of the light-emitting element 20 described in the first embodiment on the basis of examples 1-1 to 1-5 and comparative examples 1 and 2. FIG. 5 is a table showing characteristic values of light-emitting elements 20 that use the quantum dot layer 24 according to examples 1-1 to 1-7 and comparative examples 1 and 2.

The electrical characteristics of the light-emitting elements 20 in a case in which the value of the area filling rate, which is the percentage of the cross section 29 of the quantum dot layer 24 according to the light-emitting element 20 described above in which the plurality of quantum dots 27 are included, is changed will now be described with reference to FIG. 5. In examples 1-1 to 1-7 and comparative examples 1 and 2 shown in FIG. 5, the area filling rate of the quantum dot layer 24 is changed in a range from 90 to 30% in increments of 10%. FIG. 5 shows, as the electrical characteristics in the light-emitting element 20, threshold voltage Vₜₕ (V) of current of current-voltage characteristics, threshold voltage V₁ (V) of luminance in voltage-luminance characteristics, maximum luminance Lₘₐₓ (cd/m²), current density Jₘₐₓ (mA/cm²) at maximum luminance, and maximum luminous efficiency EQEₘₐₓ (%).

The area filling rate is expressed as a percentage of a value obtained by dividing the total area of the cross section 29 occupied by the quantum dots 27 by the entire area of the cross section 29 of the quantum dot layer 24. Note that the area filling rate does not need to satisfy the numerical range described above in the cross section 29 at every position of the quantum dot layer 24. The area filling rate in the cross section 29 cut at a position on any normal line NL of the quantum dot layer 24 need only be averaged, and the average value need only satisfy the numerical range of the area filling rate described above. Note that, in a case in which a ligand is present on the surface of the quantum dots 27, the area filling rate of the quantum dots 27 need only be calculated by the area obtained by adding the area occupied by the ligand and the area occupied by the quantum dots 27.

As described above, in the light-emitting element 20 including the quantum dot layer 24 as the light-emitting layer, injection of the positive holes 57 is naturally difficult. Therefore, when the voltage applied to the light-emitting element 20 is increased, the electrons 56 start to be injected into the quantum dot layer 24 first and then, once the voltage rises a certain extent, the positive holes 57 start to be injected into the quantum dot layer 24. The threshold voltage Vₜₕ of the current is the voltage value when either the electrons 56 or the positive holes 57 start to be injected into the quantum dot layer 24. The luminance threshold voltage V₁ is the voltage value when both the electrons 56 and the positive holes 57 are injected into the quantum dot layer 24 and the light-emitting recombination starts. In FIG. 5, the relationship V₁>Vₜₕ is satisfied in all examples, and thus it is understood that, in the light-emitting elements 20 according to the examples 1-1 to 1-7, injection of the electrons 56 always starts first. That is, in each example. Vₜₕ is the voltage value when the injection of the electron 56 starts, and V₁ is the voltage value when the injection of the positive holes 57 starts. As shown in FIG. 5, the value of Vₜₕ increases as the area filling rate decreases, and thus it is understood that the injection of electrons into the quantum dot layer 24 is suppressed by the increase in the vacancy 28.

As shown in FIG. 5, in all examples. V₁=3.5 V and Jₘₐₓ=500 mA/cm² regardless of the value of the area filling rate. In examples 1-1 to 1-7 and comparative examples 1 and 2, the value of V₁ does not change, and thus it is understood that the increase in the vacancy 28 does not have a significant effect on the injection of the positive holes 57.

As shown in FIG. 5, the light-emitting element 20 of comparative example 1 has substantially the densest filling value. The area filling rate is 90%, resulting in Vₜₕ=3.4 V, Lₘₐₓ=56000 cd/m², and EQEₘₐₓ=12%. Further, the light-emitting element 20 of example 1-1 has an area filling rate of 80%, resulting in Vₜₕ=3.42 V, Lₘₐₓ=58000 cd/m², and EQEₘₐₓ=13%. As a result of thus changing the area filling rate of the quantum dot layer 24 from 90% to 80%. Vₜₕ is increased, Lₘₐₓ is improved, and EQEₘₐₓ is improved. This is because lowering the area filling rate of the quantum dot layer 24 suppresses the electron density in the quantum dot layer 24, improves the balance between the positive holes 57 and the electrons 56, and improves the recombination rate in the quantum dot layer 24.

The light-emitting element 20 of example 1-2 has an area filling rate of 70%, resulting in Vₜₕ=3.43 V, Lₘₐₓ=59000 cd/m², and EQEₘₐₓ=14.3%. Next, the light-emitting element 20 of example 1-3 has an area filling rate of 60%, resulting in Vₜₕ=3.45 V, Lₘₐₓ=60000 cd/m², and EQEₘₐₓ=13.3%. Furthermore, the light-emitting element 20 of example 1-4 has an area filling rate of 50%, resulting in Vₜₕ=3.46 V, Lₘₐₓ=60000 cd/m², and EQEₘₐₓ=14%. As described above. EQEₘₐₓ is maximized and the luminous efficiency of the light-emitting element 20 is the highest in the light-emitting element 20 of example 1-3.

The light-emitting element 20 of example 1-5 has an area filling rate 40%, resulting in Vₜₕ=3.48 V, Lₘₐₓ=58000 cd/m², and EQEₘₐₓ=13%. Furthermore, the light-emitting element 20 of comparative example 2 has an area filling rate of 30%, resulting in Vₜₕ=3.48 V, Lₘₐₓ=52000 cd/m², and EQEₘₐₓ=10%. Thus, the luminous efficiency is further reduced in the light-emitting element 20 of comparative example 2 than in the light-emitting element 20 of comparative example 1. This is because lowering the area filling rate to 30% excessively suppresses the density of the electrons 56 in the quantum dot layer 24, disrupting the balance between the positive holes 57 and the electrons 56 and reducing the recombination rate in the quantum dot layer 24 to a greater extent than in comparative example 1.

From the results described above, in the light-emitting element 20, the area filling rate of the quantum dot layer 24 is preferably in a range from 40% to 80%, which is that of examples 1-1 to 1-5. With the area filling rate of the quantum dot layer 24 being in the range from 40% to 80%, it is possible to increase the luminous efficiency of the light-emitting element 20 to a greater extent than in the case of the 90% area filling rate in comparative example 1 and the 30% area filling rate in comparative example 2. Further, when the area filling rate of the quantum dot layer 24 is within a range from 50% to 70% as in examples 1-2 to 1-4, the luminous efficiency of the light-emitting element 20 is further increased, and thus such a range is more preferable.

The percentage of the quantum dots 27 included in the quantum dot layer 24 may be smaller on the cathode 26 side than on the anode 21 side. For example, in the thickness direction of the quantum dot layer 24, the area filling rate of the quantum dots 27 in the half region on the anode 21 side may be set to 80%, and the area filling rate of the quantum dots 27 in the half region on the cathode 26 side of the quantum dot layer 24 may be set to 40%. Accordingly, it is possible to suppress the injection of excess electrons 56 from the electron transport layer 25 to the quantum dot layer 24, and suppress the movement of the electrons 56 in the quantum dot layer 24 toward the anode 21 side and outflow to the hole transport layer 23 side. As a result, the recombination rate between the positive holes 57 and the electrons 56 in the quantum dot layer 24 can be increased, and the luminous efficiency of the light-emitting element 20 can be further improved.

### Second Embodiment

Below, the light-emitting element 20 according to a second embodiment will be described. The layered structure of the light-emitting element 20 according to the present embodiment is the same as the layered structure of the light-emitting element 20 according to the first embodiment described with reference to FIG. 2. The light-emitting element 20 according to the present embodiment differs from the light-emitting element 20 according to the first embodiment in that, in an intermediate layer adjacent to the quantum dot layer 24 between the quantum dot layer 24 and the anode 21, a plurality of protruding portions or a plurality of recessed portions are provided to the contact surface 231, which is the surface with which the quantum dot layer 24 comes into contact. Note that in the following description, description of matters common to the first embodiment are omitted as appropriate.

The protruding portion is a structural portion in which a portion of the intermediate layer protrudes from the contact surface 231 toward the quantum dot layer 24 side or a structure disposed on the contact surface 231, and the recessed portion is a structural portion in which a portion of the intermediate layer is recessed from the contact surface 231 toward the side opposite to the quantum dot layer 24. Note that the intermediate layer is, for example, a layer intermediately disposed between the anode 21 and the quantum dot layer 24, such as the hole injection layer 22 and the hole transport layer 23, and is a function layer with the contact surface 231 on which the quantum dot layer 24 is layered serving as an upper face thereof.

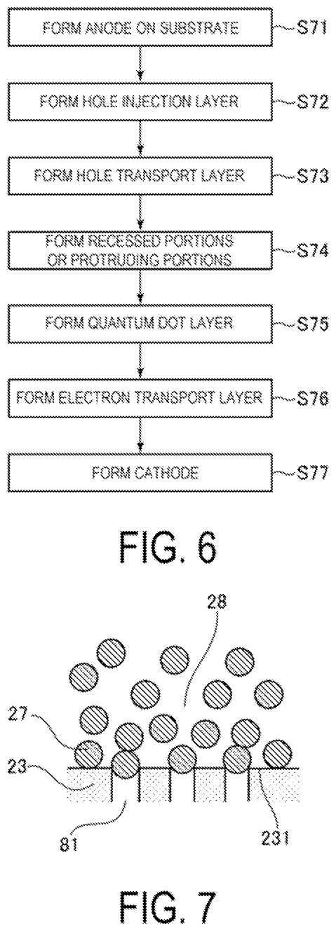

FIG. 6 is a flowchart illustrating a method for manufacturing the light-emitting element 20 according to the second embodiment. As illustrated in FIG. 2 and FIG., in the method for manufacturing the light-emitting element 20 of the present embodiment, a process of forming the anode 21 (step S71), a process of forming the hole injection layer 22 above the anode 21 (step S72), a process of forming the hole transport layer 23 above the hole injection layer 22 (step S73), a process of forming the recessed portions or the protruding portions above the hole transport layer 23 (step S74), a process of forming the quantum dot layer 24 above the hole transport layer 23 (step S75), a process of forming the electron transport layer 25 above the quantum dot layer 24 (step S76), and a process of forming the cathode 26 above the electron transport layer 25 (step S77) are performed. Other than step S74, the method is similar to that of the first embodiment, and thus description thereof will be omitted. Note that, as illustrated in FIG. 7 to FIG. 9 described below, in the present embodiment, a configuration in which the hole transport layer 23 is the intermediate layer is illustrated as an example, and the recessed portions or the protruding portions are formed in the contact surface 231 of the intermediate layer in step S74 to prepare the configuration.

In a case in which a surface roughness of the hole transport layer 23 formed in step S73 is smaller than the particle size of the quantum dots 27 of the quantum dot layer 24, the array of the quantum dots 27 is not affected. For example, if an average surface roughness of the surface of the hole transport layer 23 is in the order of 0.1 nm, the size is about one-tenth of the particle size of the typical quantum dot 27 and does not affect the array of the quantum dots 27.

In step S74, in the hole transport layer 23 that is the intermediate layer, a plurality of recessed portions 81 or a plurality of protruding portions 82 are formed in the contact surface 231, which is the surface with which the quantum dot layer 24 comes into contact. FIG. 7 to FIG. 9 are each an enlarged schematic cross-sectional view of a portion of the light-emitting element 20 according to the present embodiment, near the interface between the hole transport layer 23 and the quantum dot layer 24. The light-emitting element 20 according to the present embodiment will be specifically described below on the basis of the drawings of FIG. 7 to FIG. 9.

FIG. 7 illustrates an enlarged example of a portion of the light-emitting element according to the present embodiment, illustrating a configuration in which the plurality of recessed portions 81 recessed into the interior of the hole transport layer 23 are formed in the contact surface 231, which is the surface with which the quantum dot layer 24 of the hole transport layer 23 that is the intermediate layer comes into contact. The plurality of recessed portions 81 can be formed by, for example, applying a thermal load such as a heat treatment at a high-speed temperature rise rate to generate fine cracks in the contact surface 231 of the hole transport layer 23 as step S74 after formation of the hole transport layer 23. Subsequently, when the plurality of quantum dots 27 are applied to the contact surface 231 of the hole transport layer 23 in step S75, several of the plurality of quantum dots 27 fall into the recessed portions 81 and move away from the other adjacent quantum dots 27. As a result, the spacing of the plurality of quantum dots 27 is adjusted, and the size of the vacancy 28 can be controlled.

As another method, after formation of the hole transport layer 23, as step S74, it is possible to form the recessed portion 81 in the contact surface 231 by applying an organic solvent or a permeable liquid to the contact surface 231 of the hole transport layer 23 and subsequently applying a heat treatment of about 100 degrees, thereby causing a portion of the hole transport layer 23 to contract.

Further, step S73 and step S74 can also be performed as a series of steps. For example, when the material of the hole transport layer 23 is applied and subsequently heat treated and fixed, it is possible to form the recessed portions 81 in the contact surface 231 by rapidly increasing the temperature at the end of the heat treatment, thereby causing the solvent to volatilize at high speed and thus partially aggregate the hole transport layer 23.

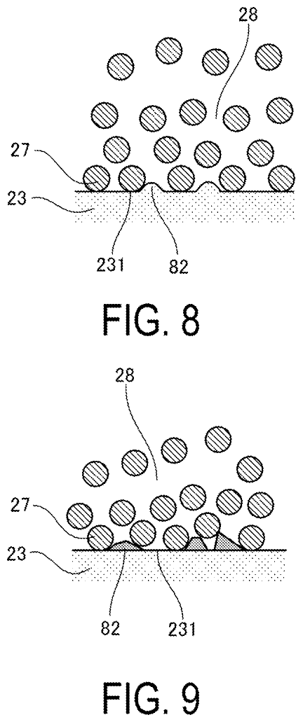

FIG. 8 illustrates an example of the present embodiment, illustrating a configuration in which the plurality of protruding portions 82 are formed on the contact surface 231, which is the surface with which the quantum dot layer 24 of the hole transport layer 23 that is the intermediate layer comes into contact. The plurality of protruding portions 82 cause the contact surface 231 of the hole transport layer 23 to partially protrude, and are thus formed integrally with the hole transport layer 23. Step S74 of forming the protruding portions 82 can be performed as a step continuous from step S73, for example. For example, when the hole transport layer 23 is formed by an application method, the viscosity of the colloidal solution that becomes the material of the hole transport layer 23 is increased. Then, the dripped colloidal solution is less likely to become flat. When the rotational speed of the spin coating is reduced in this state, the surface roughness of the contact surface 231 of the hole transport layer 23 increases and, as illustrated in FIG. 8, the plurality of protruding portions 82 can be formed on the contact surface 231 of the hole transport layer 23.

For example, while the viscosity of a typical colloidal solution is about 2 mPa·s, when the concentration of the solvent used for the material of the hole transport layer 23 is changed to increase the viscosity to about 4 mPa·s, the protruding portions 82 are distributed on the contact surface 231 of the hole transport layer 23. When the quantum dots 27 applied in step S75 are on the protruding portions 82, the quantum dots 27 move, falling off of the protruding portions 82. The distance between the moved quantum dots 27 and the other adjacent quantum dots 27 increases, making it possible to control the size of the vacancy 28 generated between these quantum dots 27.

FIG. 9 illustrates an example of the present embodiment, illustrating a case in which the plurality of protruding portions 82 of the contact surface 231, which is the surface with which the quantum dot layer 24 of the hole transport layer 23 that is then intermediate layer comes into contact, is formed separately from the hole transport layer 23. These protruding portions 82 can be formed by spraying fine particles of a dielectric, a semiconductor, or the like onto the contact surface 231 of the hole transport layer 23 in step S74, after formation of the hole transport layer 23 in step S73. Note that, in the case of a structure in which the light-emitting element 20 outputs light to the anode 21 side, the material forming the protruding portions 82 in FIG. 9 is preferably a material that is less likely to interfere with the light output from the quantum dot layer 24 and, for example, particles formed of a light-transmissive material such as glass beads are suitable.

The average surface roughness of the surface of the hole transport layer 23 increases by the recessed portions 81 or the protruding portions 82 described with reference to FIG. 7 to FIG. 9. In step S75, the quantum dots 27 applied to the surface of the hole transport layer 23 move by hitting the recessed portions 81 or the protruding portions 82, thereby adjusting the distance between the plurality of quantum dots 27 and generating the vacancy 28. Accordingly, the spacing between the plurality of quantum dots 27 adjacent to each other can be adjusted as desired and the vacancy 28 of any desired size can be provided. As a result, the respective percentages of the cross-sectional area occupied by the quantum dots 27 and the vacancy 28 at a lowermost portion of the quantum dot layer 24 can be determined.

In the present embodiment, in step S74, the plurality of recessed portions 81 or the plurality of protruding portions 82 are provided on the contact surface 231 of the hole transport layer 23. The average surface roughness of the contact surface 231 of the hole transport layer 23 increases by these recessed portions 81 or protruding portions 82. The quantum dots 27 applied to the contact surface 231 of the hole transport layer 23 move by hitting the recessed portions 81 or the protruding portions 82, thereby adjusting the spacing of the plurality of quantum dots 27 and generating the vacancy 28. Accordingly, the spacing of the plurality of quantum dots 27 adjacent to each other can be adjusted as desired and the vacancy 28 of any desired size can be provided. As a result, the respective percentages of the cross-sectional area occupied by the quantum dots 27 and the vacancy 28 at a lowermost portion of the quantum dot layer 24 can be determined.

The spacing between the plurality of quantum dots 27 layered in a layer further above the lowermost portion of the quantum dot layer 24 is affected by the array of the plurality of quantum dots 27 of the layer below. Thus, according to the array of the quantum dots 27 in the layer below, the respective percentages of the cross-sectional area occupied by the quantum dots 27 and the vacancy 28 can be determined in positions above the lowermost portion of the quantum dot layer 24 as well. Accordingly, by the plurality of recessed portions 81 or the plurality of protruding portions 82 on the contact surface 231 of the hole transport layer 23, the respective percentages of the cross-sectional area occupied by the quantum dots 27 and the vacancy 28 across an entire thickness direction of the quantum dot layer 24 can be determined. As a result, layering can be performed so that both the plurality of quantum dots 27 and the vacancy 28 in the quantum dot layer 24 are included across the entire region of the quantum dot layer 24, in all cross sections 29 of the quantum dot layer 24.

For example, the plurality of recessed portions 81 or the plurality of protruding portions 82 need only have a size in a height direction or a width direction thereof that is equal to or greater than the particle size of the quantum dots 27. For example, in a case in which the particle size of the quantum dots 27 is from about 2 to 15 nm, the height and the width of the recessed portions 81 or the protruding portions 82 need only be from about 2 to 15 nm on average. Accordingly, the recessed portions 81 or the protruding portions 82 readily affect the array of the quantum dots 27, making it possible to easily adjust the area filling rate of the quantum dot layer 24.

An in-plane density of the recessed portions 81 or the protruding portions 82 on the contact surface 231 of the intermediate layer may be adjusted so that the spacing between the plurality of recessed portions 81 or the plurality of protruding portions 82 is within 10 times the particle size of the quantum dots 27 on average across the entire contact surface 231 of the hole transport layer 23 on which the quantum dot layer 24 is layered. Accordingly, the distribution in the formation surface of the plurality of recessed portions 81 or the plurality of protruding portions 82 can be made more uniform. As a result, the plurality of quantum dots 27 and the vacancy 28 can be more uniformly distributed in all cross sections 29 of the quantum dot layer 24. Note that “across the entire contact surface 231” refers to the entire region in which the contact surface 231 is in contact with the quantum dot layer 24.

As described above, the area filling rate of the quantum dot layer 24 can be adjusted to a desired value by appropriately adjusting the size of the plurality of recessed portions 81 or the plurality of protruding portions 82, the in-plane density of the plurality of recessed portions 81 or the plurality of protruding portions 82 across the entire contact surface 231 of the hole transport layer 23 on which the quantum dot layer 24 is layered, or the like.

Although the present embodiment illustrates a case in which the hole transport layer 23 is the intermediate layer, the disclosure is not limited to this configuration. For example, in a case in which the hole transport layer 23 does not exist, the hole injection layer 22 may be used as the intermediate layer. Further, a transparent conductive film may be formed in advance on a surface that forms the quantum dot layer 24, and the transparent conductive film may be the intermediate layer.

The present invention is not limited to the embodiments described above. Embodiments obtained by modifying the embodiments described above and embodiments obtained by appropriately combining technical approaches disclosed in the embodiments described above also fall within the technical scope of the present invention.

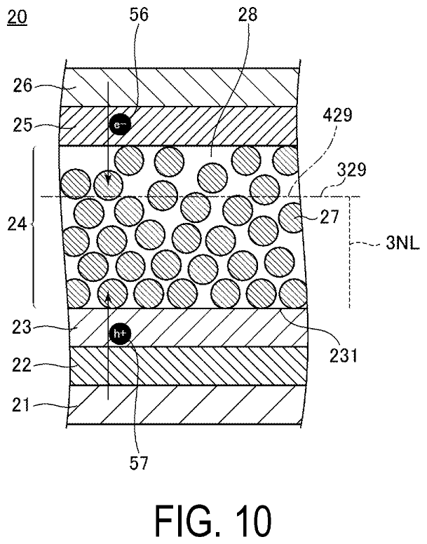

Using FIG. 10, the configuration of an embodiment of the present invention can also be described as follows. FIG. 10 illustrates the quantum dot layer 24 in a cross section obtained by cutting the light-emitting element 20 at a first cross section, which is a cross section parallel to the direction from the anode 21 toward the cathode 26. The quantum dot layer 24 emits light as a result of an occurrence of recombination between the positive holes 57 injected from the anode 21 and the electrons 56 injected from the cathode 26. The quantum dot layer 24 is provided between the anode 21 and the cathode 26. The quantum dot layer 24 includes the quantum dots 27 that are nano-sized semiconductor particles and the vacancy 28 that is a region in which the quantum dots 27 are not included. Given direction 3NL as the direction from the anode 21 toward the cathode 26 in the quantum dot layer 24 and a second cross section 329 as all cross sections orthogonal to the direction 3NL, all intersecting lines 429 of the first cross section and the second cross section 329 cross both the plurality of quantum dots 27 and the vacancy 28 in the first cross section. In the present embodiment, the quantum dot layer 24 is provided in contact with the contact surface 231, which is the surface of the hole transport layer 23.

The second cross section 329 is a virtual plane when, with respect to a plane of the quantum dot layer 24 on the cathode 26 side and a plane of the quantum dot layer 24 on the anode 21 side, the quantum dot layer 24 is cut in a direction parallel to both of these planes (left-right direction in FIG. 10). Further, the intersecting line 429 is a virtual line segment of a portion where an intersecting line between the first cross section and the second cross section 329, which is a virtual plane obtained by cutting the quantum dot layer 24 at a cross section parallel to the direction 3NL from the anode 21 toward the cathode 26, crosses the quantum dot layer 24. Further, a direction parallel to the second cross section 329 may be referred to as a horizontal direction. Further, the second cross section 329 can also be expressed as being orthogonal to the thickness direction of the quantum dot layer 24. The direction 3NL is a virtual line that extends in a direction orthogonal to the second cross section 329 (up-down direction in FIG. 10), that is, in a direction parallel to the first cross section. Further, the direction in which the direction 3NL extends may be referred to as a vertical direction. Further, the direction 3NL can also be expressed as being parallel to the thickness direction of the quantum dot layer 24. That is, in the quantum dot layer 24, the vacancy 28 and the quantum dots 27 are disposed so that the intersecting lines 429 of the first cross section and the second cross section 329 always cross both the vacancy 28 and the quantum dots 27 in the first cross section, even when the second cross section 329 orthogonal to the thickness direction is cut at any position (arbitrary position) in the thickness direction of the quantum dot layer 24.

The outer shape of the quantum dots 27 is a spherical shape, and thus the entire region of the quantum dot layer 24 cannot be filled with the quantum dots 27, in principle. Thus, the vacancy 28 always exists in the quantum dot layer 24. Accordingly. “always cross both the vacancy 28 and the quantum dots 27” in the description above specifically means that, in the first cross section in the quantum dot layer 24, at any position in the thickness direction, there is no intersecting line 429 that crosses only the vacancy 28, and the intersecting line 429 always crosses the quantum dots 27.

As is understood from the description of FIG. 10 above, the observation cross section illustrated in FIG. 10 does not necessarily have to be observed using such a cross section that crosses the quantum dot layer 24 in the left-right direction in FIG. 10, observation of a cross section having a width that allows observation of several quantum dots in the left-right direction in FIG. 10 is sufficient, and the effect of the present embodiment is achieved in a case in which the above-described configuration is confirmed by the observation. That is, observation using a cross section having a width that allows confirmation that, from the upper portion to the lower portion of the quantum dot layer 24 in the thickness direction, the intersecting line 429 crosses both the vacancy 28 and the quantum dots 27 or the intersecting line 429 crosses the quantum dots 27 is sufficient, and the effect of the present embodiment is achieved in a case in which such confirmation is made.

For example, the light-emitting element 20 includes the anode 21, the cathode 26, and the quantum dot layer 24 provided between the anode 21 and the cathode 26 and including the plurality of quantum dots 27 and the vacancy 28, the vacancy 28 being a region between the plurality of quantum dots 27. Given the first cross section as at least one cross section among cross sections of the quantum dot layer 24 parallel to the direction 3NL from the anode 21 toward the cathode 26, and the second cross section 329 as all cross sections orthogonal to the direction, all intersecting lines of the first cross section and the second cross section 329 cross both the plurality of quantum dots 27 and the vacancy 28 in the first cross section.

Further, for example, the light-emitting element 20 includes the anode 21, the cathode 26, and the quantum dot layer 24 provided between the anode 21 and the cathode 26 and including the plurality of quantum dots 27 and the vacancy 28, the vacancy 28 being a region between the plurality of quantum dots 27. Given the first cross section as at least one cross section among the cross sections of the quantum dot layer 24 parallel to the direction 3NL from the anode 21 toward the cathode 26, and the second cross section 329 as all cross sections orthogonal to the direction, all intersecting lines of the first cross section and the second cross section 329 cross the plurality of quantum dots 27 in the first cross section.

The percentage of the quantum dots 27 included in the quantum dot layer 24 may be smaller on the cathode 26 side than on the anode 21 side. Accordingly, it is possible to suppress the injection of excess electrons 56 from the electron transport layer 25 to the quantum dot layer 24, and suppress the movement of the electrons 56 in the quantum dot layer 24 toward the anode 21 side and outflow to the hole transport layer 23 side. As a result, the recombination rate between the positive holes 57 and the electrons 56 in the quantum dot layer 24 can be increased, and the luminous efficiency of the light-emitting element 20 can be further improved.

1. A light-emitting element comprising:
an anode;
a cathode; and
a quantum dot layer provided between the anode and the cathode and including a plurality of quantum dots and a vacancy, the vacancy being a region between the plurality of quantum dots,
wherein the quantum dot layer includes both the plurality of quantum dots and the vacancy in the quantum dot layer in each of all cross sections orthogonal to a normal line, the normal line being a direction from the cathode toward the anode,
wherein a percentage of the quantum dots included in the quantum dot layer is smaller on the cathode side than on the anode side.

2. The light-emitting element according to claim 1,
wherein the quantum dot layer has an area filling rate from 40% to 80%, the area filling rate being a percentage of each of all cross sections orthogonal to the normal line occupied by the plurality of quantum dots in the quantum dot layer.

3. The light-emitting element according to claim 1, further comprising:
an intermediate layer adjacent to the quantum dot layer, between the quantum dot layer and the anode,
wherein a plurality of protruding portions are formed on a contact surface of the intermediate layer, the contact surface contacting with the quantum dot layer.

4. The light-emitting element according to claim 3,
wherein the plurality of protruding portions are formed integrally with the intermediate layer.

5. The light-emitting element according to claim 3,
wherein the plurality of protruding portions are formed separately from the intermediate layer.

6. The light-emitting element according to claim 1, further comprising:
an intermediate layer adjacent to the quantum dot layer, between the quantum dot layer and the anode,
wherein a plurality of recessed portions are formed recessed from a contact surface of the intermediate layer to an interior of the intermediate layer, the contact surface contacting with the quantum dot layer.

7. (canceled)

8. A display device comprising:
the light-emitting element according to claim 1.

9-11. (canceled)

12. A light-emitting element comprising:
an anode;
a cathode; and
a quantum dot layer provided between the anode and the cathode and including a plurality of quantum dots and a vacancy, the vacancy being a region between the plurality of quantum dots,
wherein, given a first cross section as at least one cross section among cross sections of the quantum dot layer parallel to a direction from the anode toward the cathode, and a second cross section as each of all cross sections orthogonal to the direction, each of all intersecting lines of the first cross section and the second cross section cross both the plurality of quantum dots and the vacancy in the first cross section,
wherein a percentage of the quantum dots included in the quantum dot layer is smaller on the cathode side than on the anode side.

13. A light-emitting element comprising:
an anode;
a cathode; and
a quantum dot layer provided between the anode and the cathode and including a plurality of quantum dots and a vacancy, the vacancy being a region between the plurality of quantum dots,
wherein, given a first cross section as at least one cross section among cross sections of the quantum dot layer parallel to a direction from the anode toward the cathode, and a second cross section as each of all cross sections orthogonal to the direction, each of all intersecting lines of the first cross section and the second cross section cross the plurality of quantum dots in the first cross section,
wherein a percentage of the quantum dots included in the quantum dot layer is smaller on the cathode side than on the anode side.

14. (canceled)
